(19) United States
(12) Patent Application Publication
(10) Pub. No.: US 2024/0332130 A1
(43) Pub. Date: Oct. 3, 2024

(54) HIGH DENSITY VERTICAL INTERCONNECT

(71) Applicant: INTERNATIONAL BUSINESS MACHINES CORPORATION, ARMONK, NY (US)

(72) Inventors: Joshua M. Rubin, Albany, NY (US); Marc A. Bergendahl, Rensselaer, NY (US)

(21) Appl. No.: 18/192,989

(22) Filed: Mar. 30, 2023

(51) Int. Cl. H01L 23/48; H01L 21/768

(52) U.S. Cl. CPC H01L 23/481; H01L 21/76898; H01L 21/6835; H01L 2221/68359

(57) ABSTRACT

Aspects of the present invention provide a semiconductor structure. The semiconductor structure may include a first horizontally-fabricated semiconductor die section and a vertical interconnect (VI) die perpendicularly oriented to the first semiconductor die section. The VI die may include vertical metal interconnect lines electrically connecting components above and below the VI die.

### BACKGROUND

The present invention relates generally to the field of semiconductor fabrication, and more particularly to embedding a horizontally fabricated die into a vertical position on a wafer or chip package.

Multi die Wafer level packaging (MDWLP) is the technology of packaging dies, along with protective layers and electrical connections, to a substrate of an integrated circuit (IC) wafer before the IC wafer is diced into individual chips. MDWLP differs from other packaging techniques, where wafers are diced into individual chips, then packaged with the dies, protective layers, and electrical connections. Utilizing MDWLP technology allows further reduction of the size of the individual chips, streamlines manufacturing, and provides easier ways to test chip functionality. In MDWLP, top layers and bottom layers of the packaging components and the solder bumps are attached to a reconstructed wafer. This process again differs from a conventional process, in which the wafer is sliced into individual circuits (dice) before the packaging components are attached.

MDWLP results in a package that can be similar in size to the die. Multi die Wafer level packaging allows integration of wafer fab, packaging, test, and burn-in at wafer level in order to streamline the manufacturing process undergone by a device from silicon start to customer shipment. One example of MDWLP used in optics is the CCD sensor used in certain smartphone cameras.

### SUMMARY

In one aspect, the present invention provides a semiconductor structure. The semiconductor structure may include a first horizontally-fabricated semiconductor die section and a vertical interconnect (VI) die perpendicularly oriented to the first semiconductor die section. The VI die may include vertical metal interconnect lines electrically connecting components above and below the VI die.

In another aspect, the present invention provides a semiconductor structure. The semiconductor structure may include a first vertical interconnect (VI) die with vertical metal interconnect lines, a top connection layer electrically connecting the VI die to components above the VI die, and a bottom connection layer electrically connecting the VI die to components below the VI die.

In yet another aspect, the present invention provides a semiconductor structure. The semiconductor structure may include a first horizontally-fabricated semiconductor die section with an active front-end-of-line (FEOL) layer and a back-end-of-line (BEOL) system and a vertical interconnect (VI) die. The VI die may include a substrate oriented vertically relative to the major surface and metal interconnect lines within the substrate oriented vertically relative to the major surface.

### BRIEF DESCRIPTION OF THE DRAWINGS

FIGS. 1A and 1B depict a cross-sectional side view of a semiconductor structure with an embedded vertical interconnect die, in accordance with one embodiment of the present invention.

FIG. 2 depicts a cross-sectional top-down view of a semiconductor structure with an embedded vertical interconnect die, in accordance with one embodiment of the present invention.

FIG. 3 depicts a cross-sectional top-down view of a vertical interconnect die, in accordance with one embodiment of the present invention.

FIGS. 4A-C depict cross-sectional side view of a vertical interconnect die at stages of a dicing process, in accordance with one embodiment of the present invention.

FIG. 5 depicts a cross-sectional side view of a combination vertical interconnect die, in accordance with one embodiment of the present invention.

FIG. 6 depicts a cross-sectional side view of a vertical interconnect die, in accordance with one embodiment of the present invention.

FIGS. 7A-7G depict cross-sectional side views of a semiconductor structure at stages of embedding an embedded vertical interconnect die, in accordance with one embodiment of the present invention.

FIG. 8 depicts a cross-sectional side view of a semiconductor structure at stages of embedding an embedded vertical interconnect die, in accordance with one embodiment of the present invention.

FIGS. 9A-9B depict cross-sectional side views of a semiconductor structure at stages of forming an embedded vertical interconnect die, in accordance with one embodiment of the present invention.

FIG. 10 depicts a cross-sectional side view of a semiconductor structure with an embedded vertical interconnect die, in accordance with one embodiment of the present invention.

FIG. 11 depicts a cross-sectional side view of a semiconductor structure with an embedded vertical interconnect die, in accordance with one embodiment of the present invention.

### DETAILED DESCRIPTION

In the following detailed description, reference is made to the accompanying drawings, which show specific examples of embodiments of the invention. These embodiments are described in sufficient detail to enable those skilled in the art to practice them, and it is to be understood that other embodiments may be utilized, and that structural, logical, and electrical changes may be made without departing from the described embodiments. The following detailed description is, therefore, not to be taken in a limiting sense, and the included embodiments are defined by the appended claims.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

References in the specification to “one embodiment,” “an embodiment,” “certain embodiments,” etc., indicate that the embodiment described may include a particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “right,” “left,” “vertical,” “horizontal,” “top,” “bottom,” and derivatives thereof shall relate to the disclosed structures and methods, as oriented in the drawing Figures. The terms “above,” “below,” “positioned on,” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements. With regard to the fabrication of transistors and integrated circuits, major surface refers to that surface of the semiconductor layer in and about which a plurality of transistors are fabricated, e.g., in a planar process. As used herein, the term “vertical” means substantially orthogonal with respect to the major surface and “horizontal” means substantially parallel to the major surface. Typically, the major surface is along a plane of a monocrystalline silicon layer on which transistor devices are fabricated.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present. Each reference number may refer to an item individually or collectively as a group. For example, vertical interconnect die 102 may refer to a single vertical interconnect die 102 or multiple vertical interconnect dies 102.

The present invention will now be described in detail with reference to the Figures.

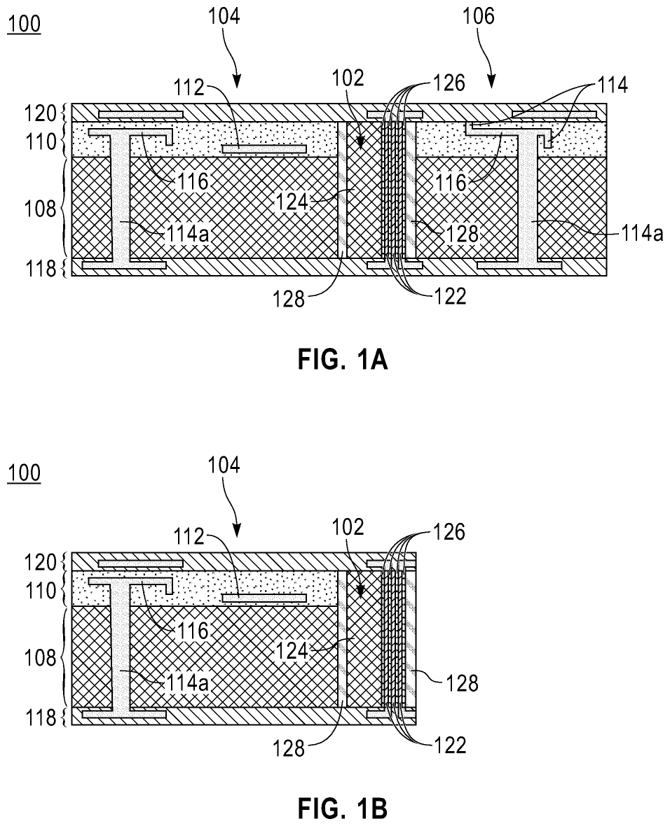

FIG. 1A depicts a cross-sectional side view of a semiconductor structure 100 with an embedded vertical interconnect (VI) die 102, in accordance with one embodiment of the present invention. The VI die 102 is embedded between a first horizontally-fabricated die section 104 and a second horizontally-fabricated die section 106 of the semiconductor structure 100. Horizontal means that the components of the first horizontally-fabricated semiconductor die section 104, for example, are formed on the major surface of the semiconductor structure 100. The first horizontally-fabricated die section 104 and the second horizontally-fabricated die section 106 are not to scale, but each may include a front-end-of-line (FEOL) layer 108 and a back-end-of-line (BEOL) system 110. While an active FEOL layer 108 is described in this embodiment, the first horizontally-fabricated die section 104 and the second horizontally-fabricated die section 106 may also include passive layers. The FEOL layer 108 refers to the layer that results from the set of processing steps that are performed in the early stages of fabricating the semiconductor structure 100. The FEOL layer 108 includes the active components of the device, such as the transistors, diodes, and resistors, on the surface of the silicon substrate. The FEOL layer 108 typically begins with the creation of a thin layer of oxide on the surface of the silicon substrate, followed by the deposition of various materials, such as polysilicon and metal, which are used to form the various components of the device. The FEOL layer 108 also involves the use of various patterning and etching techniques to define the shapes and sizes of the components, as well as the doping of the silicon substrate to create regions of different electrical conductivity.

The BEOL system 110 involves the formation of interconnects 112 that connect the active components of the FEOL layer 108. These interconnects 112 are made of various metals, such as copper, and insulating materials, such as silicon dioxide or low-k dielectrics. The BEOL system 110 also involves the creation of various structures, such as vias 114 and trenches 116, which allow the interconnects 112 to make connections between the different layers of the semiconductor structure 100. Some of the vias 114 include through-silicon vias (TSVs) 114a formed through the FEOL layer 108. These TSVs 114a connect the BEOL system 110 to a bottom connection layer 118. The TSVs 114a may require a relatively wide cut area to ensure that the etching protrudes all the way through the FEOL layer 108. Rather than relying wholly on TSVs 114a to connect the bottom connection layer 118 to the BEOL system 110 and a top connection layer 120 therefore, the semiconductor structure 100 of FIG. 1 includes the VI die 102 that includes vertical metal interconnect lines 122 connecting components above and below the VI die 102. The vertical metal interconnect lines 122 are fabricated before the VI die 102 is embedded. The vertical metal interconnect lines 122 may be fabricated in a horizontal process which enables a density that is ten to fifty times higher than the density achieved by fabricating the TSVs 114a. Each of the vertical metal interconnect lines 122 may be fabricated on a VI substrate 124 and insulated from the other vertical metal interconnect lines 122 by a dielectric insulating layer 126, as explained in detail below. The VI die 102 is further insulated from the first horizontally-fabricated die section 104 and the second horizontally-fabricated die section 106 of the semiconductor structure 100 using a fill material 128. FIG. 1A may also represent orientations in which the VI die 102 is surrounded on four sides by a single horizontally-fabricated die. That is, the horizontally-fabricated die 104 and the second horizontally-fabricated die 106, in certain embodiments, may be the same component that is also located in front and behind the VI die 102 relative to the view in FIG. 1A.

FIG. 1B illustrates an alternate embodiment where only a single horizontally-fabricated die 104 exists adjacent to the VI die 102. This can also represent one side of a horizontally-fabricated die 104 where a plurality of VI dies 102 may be place adjacent to one or more horizontally-fabricated dies 104, a gap or notch within one or more horizontally-fabricated die, or any tessellatory or non-tessellatory relation within one plane or multiple planes of construction. FIG. 1B may also depict orientations in which the VI die 102 is surrounded on two sides by the first horizontally-fabricated semiconductor die section (i.e., the left side and the front or back side relative to the view in FIG. 1B), and surrounded on three sides by the first horizontally-fabricated semiconductor die section (i.e., the left side and the front and back side relative to the view in FIG. 1B).

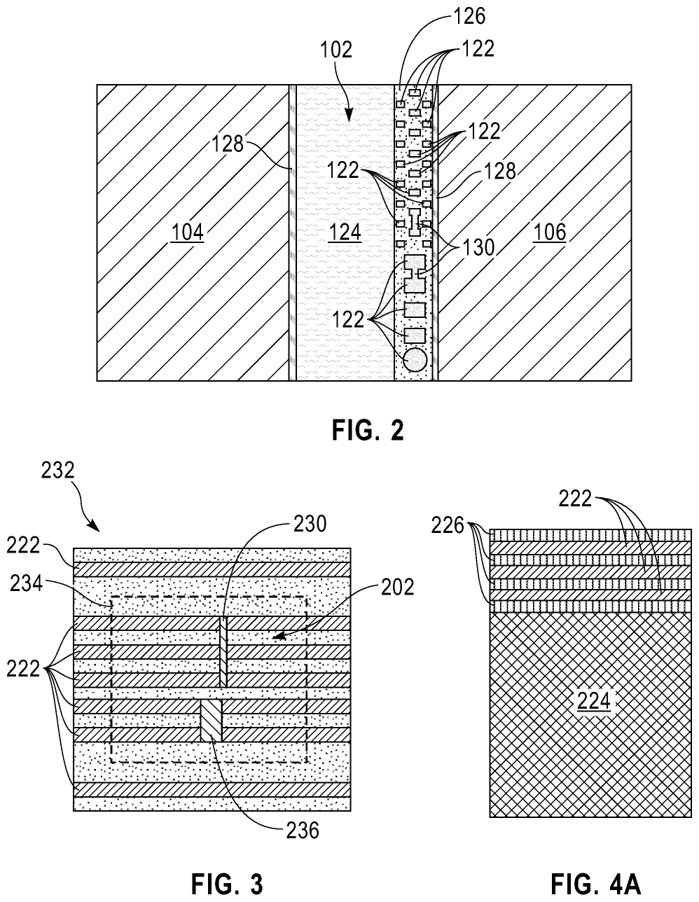

FIG. 2 depicts a cross-sectional top-down view of the semiconductor structure 100 of FIG. 1 with the embedded VI die 102, in accordance with one embodiment of the present invention. The VI die 102 is embedded between the first horizontally-fabricated die section 104 and the second horizontally-fabricated die section 106, with the fill material 128 isolating and electrically insulating the VI die 102 from the first horizontally-fabricated die section 104 and the second horizontally-fabricated die section 106. Any active devices, interconnects 112, vias 114, and trenches 116 are not illustrated in FIG. 2 to simplify the view of the VI die 102. The top-down view shows that the vertical metal interconnect lines 122 may be distributed throughout the dielectric insulating layer 126. The vertical metal interconnect lines 122 may be fabricated identically, and distributed uniformly throughout the dielectric insulating layer 126. In certain embodiments (like the illustrated embodiment in FIG. 2), the vertical metal interconnect lines 122 may be fabricated with different sizes and shapes. Additionally or alternatively, the VI die 102 may include active and passive devices (e.g., transistors, diodes, resistors) fabricated among the vertical metal interconnect lines 122. The active devices are fabricated horizontally in the typical fashion known in the art prior to singulation of the VI die 102. Preceding the embedding of the VI die 102, the active devices are fabricated within the semiconductor structure 100 and are subsequently operated through signals propagated through the vertical metal interconnect lines 122. Some vertical metal interconnect lines 122 may also be fabricated to extend only partially from the bottom connection layer 118 or from the top connection layer 120, and other vertical metal interconnect lines 122 may be fabricated as connecting lines 130 to enable effective signal propagation between vertical metal interconnect lines 122.

FIG. 3 depicts a cross-sectional top-down view of a VI die 202, in accordance with one embodiment of the present invention. The VI die 202 is fabricated initially as a VI die chip 232 containing potentially many VI dies. The VI die chip 232 includes metal interconnect lines 222, connecting lines 230, and active devices 236 fabricated using known etch and deposition techniques for fabricating active devices and wire connections in typical horizontally-installed/operated dies. That is, successive layers of conductive materials, insulators, and semiconductor material may be built up in patterns to produce the metal interconnect lines 222, connecting lines 230, and active devices 236 such as non-rectilinear lines, airgaps between the vertical metal interconnect lines, low-k dielectric between the vertical metal interconnect lines, capping layers for vertical metal interconnect lines, nonconformal and nonsymmetric features, and back-end-of-line features that will be embedded vertically into a semiconductor structure as part of the VI die 202.

After the fabrication of the metal interconnect lines 222, connecting lines, and active devices 236 in the VI die chip 232, the VI die 202 is then diced along dicing lines 234. The dicing lines 234 may be diced using any known dicing technique. For example, the VI die 202 may be diced using blade dicing, in which a blade (e.g., diamond blade) is used to saw the wafer into individual chips. The blade can be either a straight or circular saw, and it can be either a single or multi-blade system. The dicing may also include laser dicing, which uses a laser to ablate the wafer material along the cutting path. Laser dicing can be performed either with a continuous or pulsed laser to produce very precise cuts. A laser may also be used to create microcracks within the VI die chip 232 along a cutting path. The VI die chip 232 may then be heated, causing the microcracks to propagate and separate the VI die 202. The VI die 202 may also be diced using plasma dicing, which uses a plasma etching process to cut the wafer along the desired cutting path. Plasma dicing can produce very narrow and precise cuts, but it is typically slower than other dicing methods. The VI die 202 may also be diced using water jet dicing, which uses a high-pressure water jet is used to cut the wafer. Water jet dicing can produce very clean cuts, but it is typically slower than other dicing methods and can be limited by the thickness of the wafer. The choice of dicing method depends on several factors, including the desired cutting precision, the thickness of the wafer, and the type of material being diced. The dicing lines 234 are illustrated as a square, but the VI die 202 may be diced into any shape.

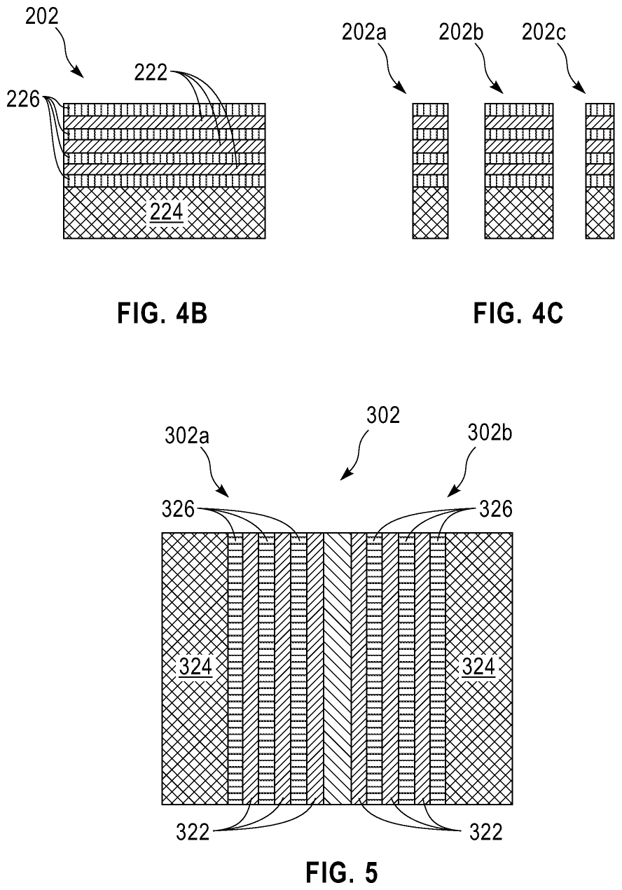

FIGS. 4A-C depict cross-sectional side views of the VI die 202 of FIG. 3 at stages of a dicing process, in accordance with one embodiment of the present invention. In a first stage illustrated in FIG. 4A, the VI die 202 includes a VI substrate 224 with the metal interconnect lines 222 fabricated horizontally above the VI substrate 224. The VI die 202 also includes a dielectric insulating layer 226 that has been built up along with the metal interconnect lines 222 during the fabrication process.

FIG. 4B illustrates another stage of forming the VI die 202. The VI die 202 has the VI substrate 224 thinned, while maintaining the integrity of the metal interconnect lines 222. The thinning of the VI substrate 224 involves reducing the thickness of the VI substrate 224 while maintaining its flatness and integrity. The VI substrate 224 may be thinned using techniques such as mechanical polishing, chemical mechanical polishing (CMP), etching, and laser ablation. The method used to thin the VI substrate 224 depends on the material of the VI substrate 224, as well as the desired precision and final thickness of the thinned VI substrate 224. Thinning of the substrate 224 may occur either before, after or at both times with respect to the initial dicing/singulation method chosen. Additionally, backside films, which can be blanket films or patterned, can be added on the backside of the VI die 202. The backside films can compensate for backside stresses that can warp the VI die 202, which can prevent assembly of the VI die 202 into the final semiconductor structure. The backside films are typically deposited before dicing, after final thickness is achieved. Post singulation thinning is illustrated in figured 4B.

FIG. 4C illustrates that the VI die 202 may be sub-divided further after the dicing and thinning processes. The VI die 202 is divided into a first VI die 202a, a second VI die 202b and a third VI die 202c. The divided VI dies 202a, 202b, 202c may be embedded into a semiconductor structure at different locations, or embedded within totally different semiconductor structures. The metal interconnect lines 222 may be the between the VI dies 202a, 202b, 202c, or each of the divided dies may have different metal interconnect lines, vias, and active devices tailored to a specific need within the separate semiconductor structures into which the VI dies 202a, 202b, 202c are eventually embedded.

FIG. 5 depicts a cross-sectional side view of a combination VI die 302, in accordance with one embodiment of the present invention. The combination VI die 302 represents one possible way of combining VI dies, but other combinations may be employed to create the combination VI die 302. The combination VI die 302 uses two VI dies: a first VI sub-die 302a and a second VI sub-die 302b. The sub-dies 302a, 302b may be formed in the process illustrated in FIGS. 4A-4C with metal interconnect lines 322 and dielectric insulating layer 326 built up above a VI substrate 324. The first VI sub-die 302a is rotated a quarter-turn in one direction so that the VI substrate 324 is on a left side. The second VI sub-die 302b is rotated a quarter-turn in the other direction so that the VI substrate 324 is on a right side. The VI sub-dies 302a, 302b are then brought together with the VI substrates 324 opposite/apart and the dielectric insulating layer 326 together to form a single component (i.e., the combination VI die 302). An adhesive or other attachment structure may be used to permanently attach the first VI sub-die 302a to the second VI sub-die 302b. The VI sub-dies 302a, b may also be attached with the rotations in the opposite direction. Fabrication of the combination VI die 302 may also include thinning and sub-dividing/dicing the sub-dies 302a, b. The thinning and dicing steps may be distributed throughout the fabrication process for the combination VI die 302. For example, two wafers (i.e., one wafer with the first VI sub-die 302a fabricated on a face, and a second wafer with the second VI sub-die 302b fabricated on a face) may be bonded face to face with adhesive, oxide bonding, hybrid bonding, or other bonding technique. Then the wafers with the sub-dies 302a, b (as the single combination VI die 302) are diced.

The sub-dies 302a, b (or the wafers) may be thinned as well, and the thinning may be done before or after adhesion of the wafers/sub-dies 302a, b. For example, one or both of the wafers may be pre-thinned and put on temporary carriers before face-to-face bonding. One or both of the wafers may be thinned after the face-to-face bonding as well. Dicing of the sub-dies 302a, b may be completed without dicing through the temporary carriers, which provides the added benefit of carrying the diced/bonded combination VI 302 with the carrier. The combination VI die 302 may then be embedded within a semiconductor structure.

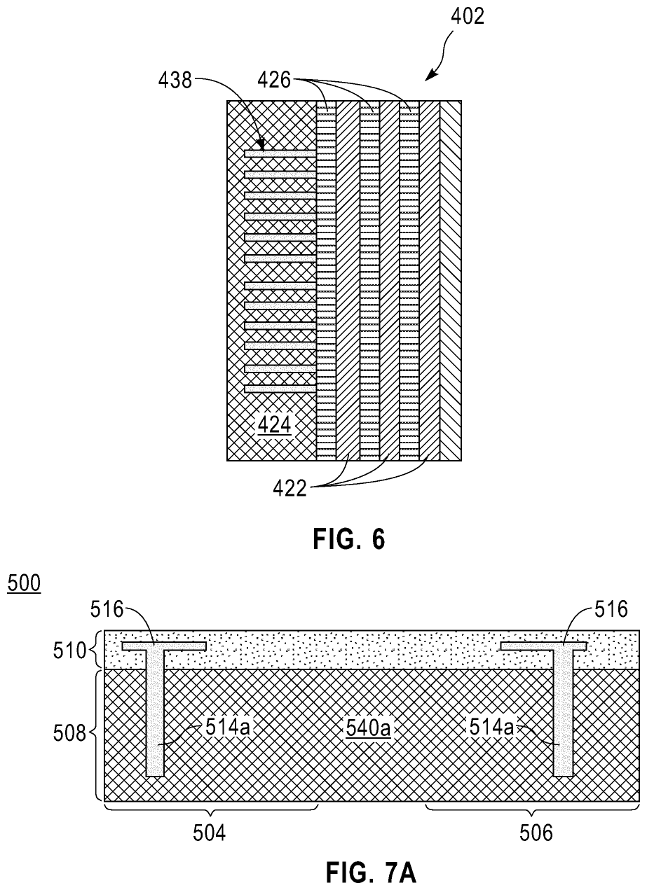

FIG. 6 depicts a cross-sectional side view of a VI die 402, in accordance with one embodiment of the present invention. The VI die 402 can include deep trench capacitor (DTC) devices 438 that can be used in semiconductor structures (e.g., semiconductor structure 100) to improve performance and reduce power consumption. Deep trench capacitor (DTC) elements are three-dimensional vertical capacitor features formed by etching a deep trench (DT) into a silicon substrate or oxide. The DTC devices 438 may also include any other type of high density capacitors, Mimcaps, etc.

The DTC devices 438 may be formed before metal interconnect lines 422 are built up along with a dielectric insulating layer 426. The VI die 402 is then rotated for embedding within a semiconductor structure. They may be formed into the VI substrate 424 and be integrated into active or passive circuitry using the metal lines 422.

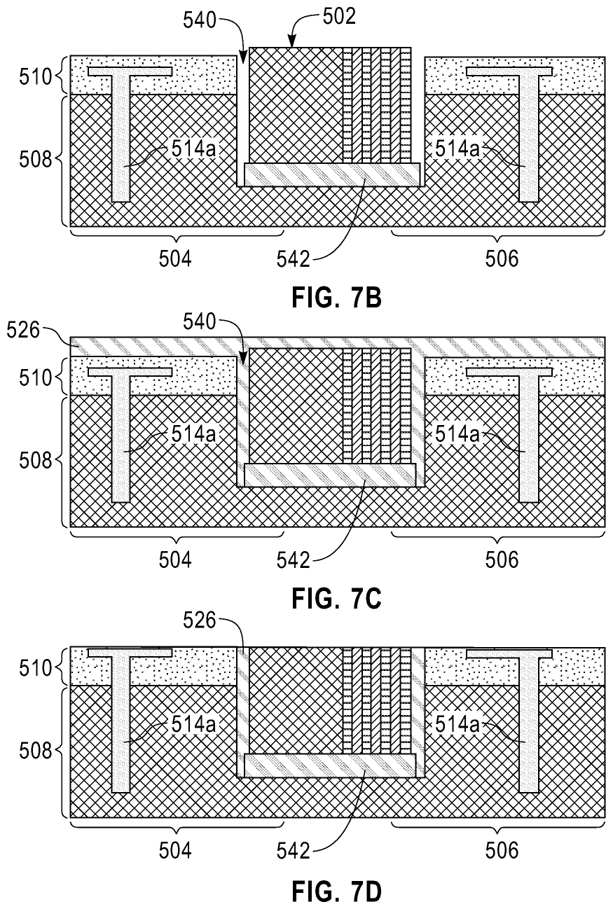

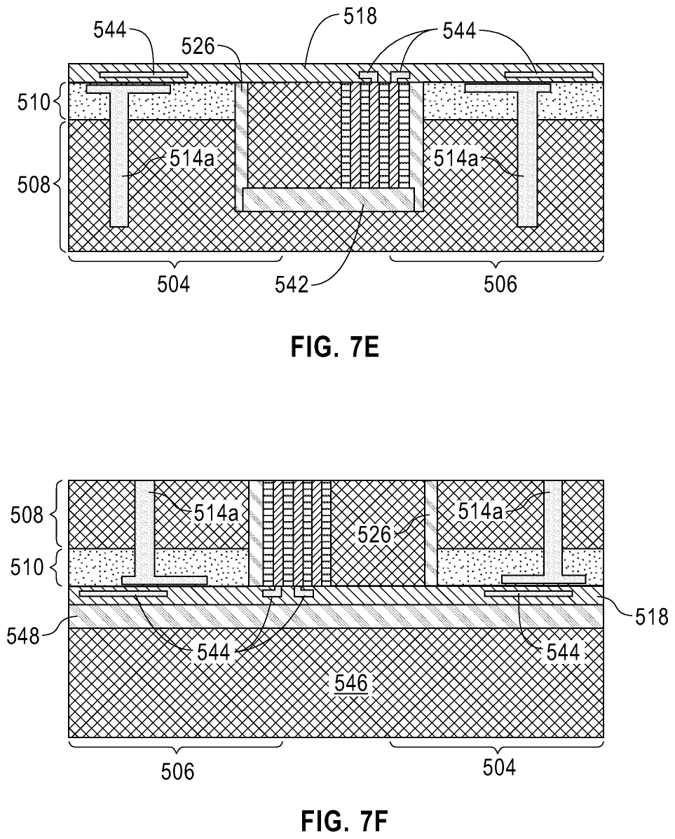

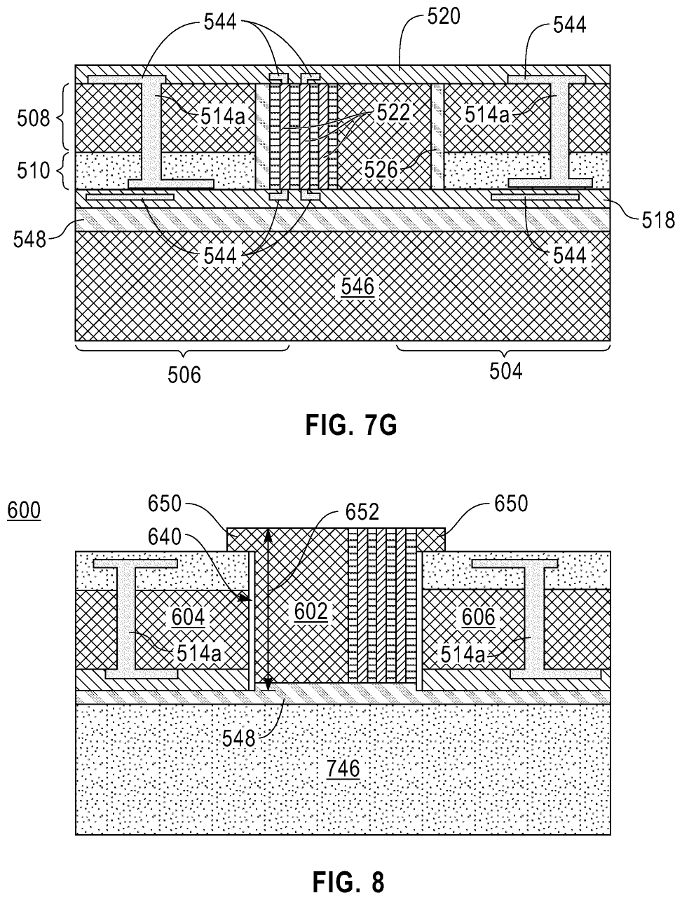

FIGS. 7A-7G depict cross-sectional side views of a semiconductor structure 500 at stages of embedding an embedded VI die 502, in accordance with one embodiment of the present invention. In FIG. 7A, the semiconductor structure 500 is fabricated at one initial stage with a first horizontally-fabricated semiconductor die section 504 and a second horizontally-fabricated semiconductor die section 506. While two sections 504, 506 are illustrated in the steps here, the VI die 502 may be embedded adjacent to a single section, with the VI die 502 embedded at the end of the semiconductor structure 500, or with the VI die 502 being embedded between the first die section 504 and a pure substrate. Additionally, the two sections 504, 506 may be part of the same die, such that the die sections 504, 506 surround the VI die 502 (which is embedded within a hole rather than a trench.

The first section 504 and second section 506 may include passive devices, wires, or active devices in a FEOL layer 508, and interconnects 512, TSVs 514a, etc. fabricated and completed along with a BEOL system 510. The semiconductor structure 500 is not fabricated with a bottom connection layer or a top connection layer at this stage. Between the first section 504 and the second section 506, the semiconductor structure 500 includes a trench spot 540a in which no other required components are included. That is, the semiconductor structure 500 may include components (e.g., trenches, wires) that pass through the trench spot 540a, but any active devices fabricated within the semiconductor structure 500 will function operably without the components in the trench spot 540a.

FIG. 7B depicts a subsequent stage of fabrication of the semiconductor structure 500. The semiconductor structure 500 has a VI die 502 embedded in a trench 540 etched in the trench spot 540a between the first section 504 and the second section 506. The VI die 502 may be fabricated in the any of the manners described above, and likewise may include any of the VI die or dies described above. To embed the VI die 502, the trench 540 may be etched using known masking and etch techniques. For example, a hard mask may be deposited and patterned with an opening over the trench spot 540a, after which a directional chemical or energetic etch process may etch the trench spot 540a without etching the remainder of the semiconductor structure 500 due to the protection of the hard mask. The VI die 502 may be embedded using an attachment structure 542 that secures the VI die 502 within the trench 540 without contacting the first section 504 or the second section 506. The attachment structure 542 may include one or more materials selected based on downstream processing requirements. For example, the attachment structure 542 may need to withstand certain temperatures, which may require higher temperature bonding films. The attachment structure 542 may be attached using a temporary or permanent bond, but typically the attachment structure 542 is removed in a later (e.g., planarization) stage of fabrication.

FIG. 7C depicts a subsequent stage of fabrication of the semiconductor structure 500. The VI die 502 is covered by a surrounding material 526. The surrounding material 526 is deposited using a blanket layer of one or more dielectric materials. For example, within the trench region (i.e., adjacent to the VI die 502) the surrounding material 526 may include a material or materials that are different from the material in the plane area above the VI die 502. The surrounding material 526 may be fabricated in a multiple step process of filling the trench 540 around the VI die 502, and subsequent planarization (removal of material above VI die 502 shown below). The surrounding material 526 could also be covering other dies and filling other trenches. The dielectric material of the surrounding material 526 forms within the trench 540 around the VI die 502 and the attachment structure 542 such that the trench 540 is completely filled without any empty space (excepting perhaps small gaps within a fabrication tolerance level). The surrounding material 526 also typically forms over the entire surface of the semiconductor structure 500.

FIG. 7D depicts a subsequent stage of fabrication of the semiconductor structure 500. The semiconductor structure 500 has the surrounding material 526 polished flat so that the BEOL system 510 is once again exposed at the top surface. The polishing also exposes the metal interconnect lines 522 and the metal components (e.g., TSVs 514a, trenches 516) within the BEOL system 510. The surrounding material 526 may be composed of Dielectrics such as flowable Oxide or Low-K Materials, spin on polymers such as benzocyclobutane (BCB), Plated materials such as pure Metals and Metal Alloys, LPCVD Ge or other materials that meet the need for filling the gap between the VI and surrounding structure and allow for subsequent planarization. In certain embodiments, the semiconductor structure 500 may be fabricated without any surrounding material 526 being formed above the VI die 502, thus removing the need to planarize the surrounding material 526.

FIG. 7E depicts a subsequent stage of fabrication of the semiconductor structure 500. The semiconductor structure 500 has a bottom connection layer 518 deposited on the semiconductor structure 500. The bottom connection layer 518 is deposited on the upper side of the semiconductor structure 500 (as oriented in FIG. 7E), but will subsequently be flipped to the bottom side at a later stage. The bottom connection layer 518 includes additional metal wires and contacts 544 that connect the metal interconnect lines 522 and the BEOL system 510 to electrical components outside of the semiconductor structure 500.

FIG. 7F depicts a subsequent stage of fabrication of the semiconductor structure 500. The semiconductor structure 500 is flipped over and attached to a carrier wafer 546, and the newly-flipped top side is polished to reveal the conductive components of the first section 504, the second section 506, and the VI die 502. The attachment structure 542 is completely removed in the illustrated embodiment, though other embodiments may keep all or part of the attachment structure 542 after polishing. The carrier wafer 546 may include an attachment layer 548 that secures the bottom connection layer 518 so that that semiconductor structure 500 remains permanently with the carrier wafer 546.

FIG. 7G depicts a subsequent stage of fabrication of the semiconductor structure 500. The semiconductor structure 500 includes a top connection layer 520 formed on the top above the VI die 502, the first section 504, and the second section 506. The top connection layer 520 includes further additional metal wires 544 that electrically connect the metal interconnect lines 522 and the BEOL system 510 to electrical components outside of the semiconductor structure 500. The semiconductor structure 500 thus includes a dense collection of vertical metal interconnect lines 522 that pass completely from the top connection layer 520 to the bottom connection layer 518, and which are highly customizable with respect to the possibilities or the number and density of vertical metal interconnect lines 522.

FIG. 8 depicts a cross-sectional side view of a semiconductor structure 600 with an embedded VI die 602, in accordance with one embodiment of the present invention. The semiconductor structure 600 includes alignment wings 650 that protrude above a horizontally-fabricated semiconductor die section 604 and a second horizontally-fabricated semiconductor die section 606. The alignment wings 650 improve the ability to place the VI die 602 straight into a trench 640 between the first section 604 and the second section 606. The VI die 602 may thus include a height 652 that is taller than the first horizontally-fabricated semiconductor die section 604 and the second horizontally-fabricated semiconductor die section 606.

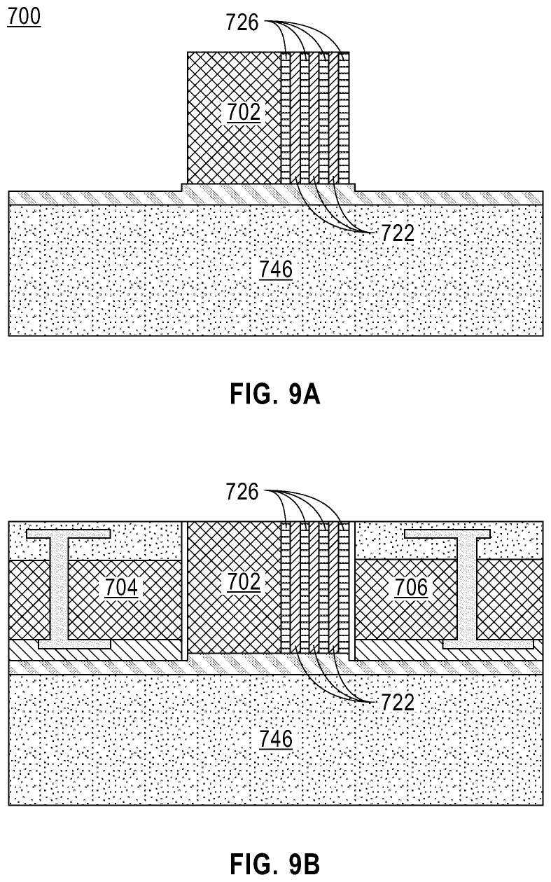

FIGS. 9A-9B depict cross-sectional side views of a semiconductor structure 700 at stages of forming an embedded VI die 702, in accordance with one embodiment of the present invention. FIG. 9A shows a VI die 702 after metal interconnect lines 722 have been fabricated, and the VI die 702 has been diced, rotated, and attached to a carrier wafer 746. The carrier wafer does not have a FEOL layer or BEOL system and is used as a mounting or positioning substrate for a VI die or dies. This order of attachment to the carrier wafer 746 may enable the VI die 702 to achieve a more secure attachment to the carrier wafer, which may be desirable in certain circumstances of use for the semiconductor structure 700 wherein the relative position or positions of the VI element(s) can be pre-arranged before introduction to subsequent substrates.

FIG. 9B shows the semiconductor structure 700 with a first horizontally-fabricated semiconductor die section 704 fabricated on a first side of the VI die 702 and a second horizontally-fabricated semiconductor die section 706 fabricated on a second side of the VI die 702. The first and second die sections 704, 706 may be formed through methods of deposition, patterning, and etching described above.

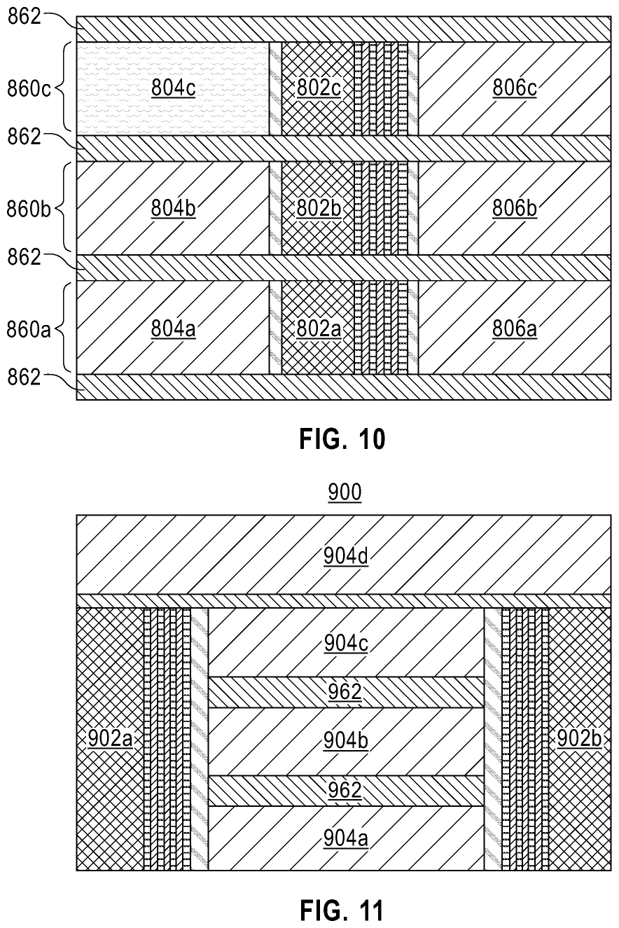

FIG. 10 depicts a cross-sectional side view of a multi-level semiconductor structure 800 with embedded VI dies 802, in accordance with one embodiment of the present invention. The semiconductor structure 800 includes a first VI die 802a at a first level 860a, a second VI die 802b at a second level 860b, and a third VI die 802c at a third level 860c. The first VI die 802a is embedded between a first first-level horizontally-fabricated semiconductor die section 804a and a second first-level horizontally-fabricated semiconductor die section 806a. The second VI die 802b is embedded between a first second-level horizontally-fabricated semiconductor die section 804b and a second second-level horizontally-fabricated semiconductor die section 806b. The third VI die 802c is embedded between a first third-level horizontally-fabricated semiconductor die section 804c and a second third-level horizontally-fabricated semiconductor die section 806c. Each of the first level 860a, the second level 860b, and the third level 860c contains a horizontally-fabricated layer (e.g., FEOL layer) and a BEOL system as described above, and is separated from the remaining layers by a connection layer 862. The connection layer 862 may be formed of dielectrics, organic materials with or without solder bumps or pillar features, or may contain multiple such films bonded together. Furthermore it may include wires that connect the VI dies 802 or the BEOL systems from one level 860a, b, c to another level 860a, b, c.

The multi-level semiconductor structure 800 may be fabricated using a variety of methods. For example, the first level 860a may be formed complete with the first VI die 802a before the second level 860b is started, followed by completely forming the second level 860b, followed by completely forming the third level 860c. More specifically, the first level 860a may be initially formed by fabricating the first section 804a and the second section 806a as one complete layer, then etching a trench, then embedding the first VI die 802a into the trench as described in FIGS. 7A-7G above. In a similar process, the second level 860b may be fabricated to completion, after which the third level 860c is fabricated to completion.

Alternatively, in certain embodiments all three levels 860a, b, c (i.e., with only the horizontally-fabricated semiconductor die sections 804a, b, c, 806a, b, c) may be formed and have the accompanying VI dies 802a, b, c are embedded within each level 860a, b, c. In these embodiments, the completed levels 860a, b, c may then be combined by stacking. That is, connection layer 862 above the first level 860a may be completed, after which the second level 860b (with the already-embedded VI die 802b) may be stacked on top of the connection layer 862. Then the next connection layer 862 above the second level 860b may be formed, and then the third level 860c (with the already-embedded VI die 802c) may then be stacked on top of the connection layer 862.

FIG. 11 depicts a cross-sectional side view of a multi-level semiconductor structure 900 with embedded VI dies 902, in accordance with one embodiment of the present invention. The semiconductor structure 900 includes a first VI die 902a and a second VI die 902b embedded on opposite sides of three levels of horizontally-fabricated semiconductor die sections 904a, b, c. Each die section 904a, b, c is fabricated with FEOL layers and BEOL systems, which are separated from the other sections 904a, b, c by attachment layers 962. The semiconductor structure 900 also includes a top horizontally-fabricated semiconductor die section 904d that is fabricated over the third section 904c, and over the first VI die 902a and the second VI die 902b. The first VI die 902a and the second VI die 902b may be fabricated using the horizontal deposition, pattern, and etch process described above, before being rotated and embedded beside the die sections 904a, b, c.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a first horizontally-fabricated semiconductor die section; and
a vertical interconnect (VI) die perpendicularly oriented to the first semiconductor die section, comprising vertical metal interconnect lines electrically connecting components above and below the VI die.

2. The semiconductor structure of claim 1, wherein the first horizontally-fabricated semiconductor die section comprises an active front-end-of-line (FEOL) layer and a back-end-of-line (BEOL) system.

3. The semiconductor structure of claim 1, wherein the VI die comprises selection from the group consisting of: active devices and connecting lines connecting at least two of the vertical metal lines.

4. The semiconductor structure of claim 1, further comprising a surrounding material between the VI die and the first horizontally-fabricated semiconductor die section.

5. The semiconductor structure of claim 1, further comprising a second horizontally-fabricated semiconductor die section, wherein the VI die is embedded in a trench between the first horizontally-fabricated semiconductor die section and the second horizontally-fabricated semiconductor die section.

6. The semiconductor structure of claim 1, wherein the vertical metal interconnect lines comprise a feature selected from the group consisting of: non-rectilinear lines, airgaps between the vertical metal interconnect lines, low-k dielectric between the vertical metal interconnect lines, capping layers for vertical metal interconnect lines, nonconformal and nonsymmetric features, and back-end-of-line features.

7. The semiconductor structure of claim 1, further comprising:
a second level comprising:
a first second-level horizontally-fabricated semiconductor die section; and
a second VI die embedded adjacent to the first second-level horizontally-fabricated semiconductor die section.

8. The semiconductor structure of claim 1, further comprising:
a second-level horizontally-fabricated semiconductor die section attached vertically above the first horizontally-fabricated semiconductor die section, wherein the VI die is embedded adjacent to the first horizontally-fabricated semiconductor die section and the second-level horizontally-fabricated semiconductor die section.

9. The semiconductor structure of claim 8, further comprising a top horizontally-fabricated semiconductor die section over the VI die and the second-level horizontally-fabricated semiconductor die section.

10. The semiconductor structure of claim 1, wherein the VI die is embedded in a hole in the first horizontally-fabricated semiconductor die section.

11. A semiconductor structure, comprising
a first vertical interconnect (VI) die comprising vertical metal interconnect lines;
a top connection layer electrically connecting the VI die to components above the VI die; and
a bottom connection layer electrically connecting the VI die to components below the VI die.

12. The semiconductor structure of claim 11, further comprising a horizontally-fabricated semiconductor die section adjacent to the first VI die and between the top connection layer and the bottom connection layer.

13. The semiconductor structure of claim 11, further comprising a second VI die above the top connection layer.

14. The semiconductor structure of claim 13, further comprising a horizontally-fabricated semiconductor die section adjacent to the second VI die.

15. A semiconductor structure, comprising:
a first horizontally-fabricated semiconductor die section comprising an active front-end-of-line (FEOL) layer and a back-end-of-line (BEOL) system; and
a vertical interconnect (VI) die comprising:
a substrate oriented vertically relative to the major surface; and
metal interconnect lines within the substrate oriented vertically relative to the major surface.

16. The semiconductor structure of claim 15, wherein the VI die comprises a height that is taller than the first horizontally-fabricated semiconductor die section.

17. The semiconductor structure of claim 15, wherein the VI die comprises an orientation selected from the group consisting of: embedded in a trench between the first horizontally-fabricated semiconductor die section and a second horizontally-fabricated semiconductor die section, attached adjacent to the first horizontally-fabricated semiconductor die section, surrounded on two sides by the first horizontally-fabricated semiconductor die section, surrounded on three sides by the first horizontally-fabricated semiconductor die section, and surrounded on four sides by the first horizontally-fabricated semiconductor die section.

18. The semiconductor structure of claim 15, wherein the VI die further comprises alignment wings that protrude above the first horizontally-fabricated semiconductor die section.

19. The semiconductor structure of claim 15, further comprising a second level comprising a second VI die embedded adjacent to a first second-level horizontally-fabricated semiconductor die section.

20. The semiconductor structure of claim 15, further comprising a second VI die bonded to the VI die, wherein the second VI die is bonded on a side of the VI die away from the substrate.
